(19) United States
(12) Patent Application Publication
(10) Pub. No.: US 2012/0015145 A1
(43) Pub. Date: Jan. 19, 2012

(54) MULTILAYER PRINTABLE SHEET WITH A SOFT OR SILKY TOUCH AND MANUFACTURING METHOD THEREOF

(75) Inventor: Gael Depres, Chirens (FR)

(73) Assignee: ARJO WIGGINS FINE PAPERS LIMITED, Manchester (GB)

(21) Appl. No.: 13/201,167

(22) PCT Filed: Feb. 12, 2010
(86) PCT No.: PCT/FR2010/000114

§ 371 Date: Sep. 23, 2011

(30) Foreign Application Priority Data
Feb. 13, 2009 (FR) 0900684

(51) Int. Cl. B32B 15/08; B32B 38/14; B32B 38/00; B32B 27/00; C23C 16/44

(52) U.S. Cl. 428/143; 428/457; 428/141; 428/464; 428/221; 156/278; 156/272.6; 156/277

(57) ABSTRACT

The invention relates to a multilayer printable sheet, including a bottom support layer, an intermediate metal layer and a top layer made of transparent or translucent plastic material, a top surface of said layer of plastic material being covered with a coating layer made of a transparent or translucent matte varnish with a soft or silky touch.

This invention relates to a multilayer sheet and the method for producing same, in which said sheet is of the type including a lower support layer, an intermediate metallic layer and an upper layer made of a transparent or translucent plastic material.

The superposition of the plastic material layer and the metallic layer confers optical properties on said sheet producing a visual effect of depth, which is beneficial in particular in terms of aesthetics. In addition, when the layer of plastic material is coloured, the sheet may have an iridescent appearance characterized by changes in reflections, tints or nuances of the sheet in particular according to the angle of observation.

This type of sheet can, for example, be used in distinct fields such as that of packaging, for example packaging of food or cosmetic products or in the field of graphic arts, for example as a printing support for advertisements or the like. In the field of packaging, the sheet can be subjected to a plurality of cutting and folding operations and must therefore have suitable mechanical properties so as not to be damaged during these operations.

A multilayer sheet comprising a plastic material layer formed by an acetate film is known, in which said film is bonded to a metallic film or to a metalized plastic film, which is itself bonded to a paper forming a support. However, this sheet has an unattractive dullness and the acetate film has a disagreeable touch. Moreover, even though the acetate film can be coloured, the number of colours available for said film is very limited. Finally, the production of this sheet requires two long and expensive sequential bonding operations: the bonding of the acetate film on the metallic film and the bonding of the metallic film on the paper.

The invention enables a simple, effective and economical solution to be applied to at least some of these problems.

It relates to a multilayer sheet that has the advantages of a sheet of this type of the prior art in terms of the visual depth effect and the iridescent appearance, without the disadvantages of the prior art, and which has good printing, embossing, plating and fashioning behaviours, in particular for bending and cutting, as well as good abrasion and scratch resistance. This sheet is therefore particularly but not exclusively suitable for applications in the field of packaging.

It thus proposes a multilayer sheet, including a lower support layer, an intermediate metallic or reflective layer and an upper transparent or translucent plastic material layer, characterized in that at least a portion of an upper face of the plastic material layer is covered by a transparent or translucent matte varnish coating layer, preferably with a soft or silky touch.

In this application, the term sheet refers to a substrate or a thin plate that is preferably flexible. This sheet is advantageously printable, i.e. it is capable of receiving an ink or the like, in particular by a printing technique.

According to the invention, a coating layer formed by a matte varnish is deposited on some or all of the upper face of the plastic material layer. This varnish layer preferably has a matte appearance and an especially agreeable soft, silky or gum-like touch. In this application, the term soft touch refers to a touch that is neither perfectly smooth nor rough, which can be due to the fact that the upper face of the coating layer has surface irregularities, preferably of low amplitude. The varnish layer forms an over-layer or an external layer of the sheet, i.e. its upper face is intended to remain bare. The sheet thus formed is nevertheless capable of receiving an ink or any other product (plating, etc.) by a printing technique or any technique. Although it may be believed that the glossy metallic appearance of the metallic layer may be cancelled or at least altered by the matte appearance of the varnish, the addition of the matte varnish on the plastic material layer on the contrary confers particularly aesthetic properties on the sheet.

The sheet according to the invention therefore has a metallic and matte visual appearance, a soft or silky touch, a visual depth effect and can also have an iridescent effect when the plastic material layer is coloured. The sheet advantageously has an optical colour “path”, i.e. the colour of the sheet changes according to the angle of incidence of the light on the sheet and/or the angle of observation. This effect is due in particular to the over-layering of the metallic layer and the matte varnish layer. The latter slightly diffracts light, and acts as a filter. When the light is incident (angle of observation at less than around 45°), the metallic layer acts as a reflective layer and the sheet appears to be very luminous and coloured. When it is observed in diffuse light (angle of observation less than 0°), the light is diffracted in the matte varnish layer and the sheet appears to be darker and less coloured.

The sheet according to the invention is also opaque, and this opacity is obtained by the presence of the metallic layer and/or the support layer.

Finally, the sheet according to the invention advantageously has abrasion and scratch resistance properties. These properties are important so that the sheet preserves the desired matte appearance. Indeed, when a scratch extends into the matte varnish layer (or the matte varnish layer is partially torn), the observer may see the glossy appearance of the plastic material layer at the level of the scratch (or the torn area) in the form of a so-called “glossy” scratch, which is detrimental to the desired aesthetic effect. If the scratch is deeper and extends also through the plastic material layer (or said layer is also partially torn), the observer can then see the metallic appearance of the metallic layer at the level of the scratch (or the torn area) in the form of a so-called “metallic” scratch, which is detrimental to the desired effect.

In a particular embodiment of the invention, each layer can, independently of the others, include a plurality of sub-layers. As an example, the lower support layer can be formed by a plurality of substrates superimposed one on another. The metallic layer can include at least two superimposed films or metallic deposits. The plastic material layer can include two or more superimposed sub-layers. The sub-layers of a same type of layer can have the same thickness or different thicknesses. The sheet according to the invention can optionally include one or more composite layers, each of which is formed by a mixture of components of the types mentioned above.

The features of each layer of the sheet according to the invention will now be described in greater detail below.

The matte varnish is deposited by coating in order to form a thin coating layer of which the thickness is relatively low, compared with that of an acetate film of the prior art, which does not enable the visual depth effect and the iridescent appearance conferred by the plastic material layer to be obstructed. The matte varnish layer can be deposited on the plastic layer in an amount of 0.1 to 30 g/m², preferably 0.5 to 10 g/m² and for example 1 to 4 g/m².

The matte varnish layer can have a composition similar to that described in the application FR-A1-2 833 625, used to produce a coated paper. The matte varnish layer thus includes pigments and a binder, with at least some of these pigments being intended to project on the upper face of said layer so as to define the aforementioned soft or silky feel of the sheet. The pigments can have a diameter of less than 10 μm, more preferably between 3 and 5 μm, and, for example, around 4 μm. These pigments can be polyurethane microbeads, for example.

Advantageously, these pigments define a relief formed by bumps and recesses on the upper face of the matte varnish layer, with the distance between the base of the recesses and the top of the bumps being, for example, less than or equal to around 3 μm. This distance corresponds substantially to the average diameter of the pigments. The relief of the upper face of the coating layer of the matte varnish therefore has a low amplitude, which confers an agreeable soft or silky touch on said coating layer. By contrast, the absence of a relief confers a smooth touch on the layer, and an excessive or large relief confers a rough touch on the layer.

The dynamic friction coefficient of the sheet according to the invention (measured according to standard NF-Q-03-082 with a 200-g slide) can be between 0.3 and 0.8, and preferably between 0.4 and 0.6. A sheet with an excessively smooth touch has a dynamic friction coefficient of less than 0.3, and a sheet with a rough touch has a dynamic friction coefficient greater than 0.8, which can then hinder certain steps of use of the sheet (fashioning, printing, and so on).

The binder of the matte varnish layer can be based on acrylic, polyurethane, polymethyl methacrylate, styrene butadiene, vinyl acetate, polyamide, nitrocellulose or any other cellulose, or a mixture of same. The amount of binder with respect to the pigments is preferably around 200% by weight. The binder advantageously has an elongation rate greater than around 500%, which confers tactile properties of flexibility and softness on the pigment-binder assembly. The binder is intended to coat the pigments and, due to its elastic properties, enables the tactile properties of these pigments to be preserved. An excessively rigid binder would indeed cause the tactile properties of the pigments to be lost.

The matte varnish layer can also include a cross-linking agent (for example based on polyaziridine, isocyanate, melamine formaldehyde, carbodiimide, epichloridrine, aldehyde or zirconium salt) intended to cause the cross-linking of said coating layer in order to reinforce its abrasion and scratch resistance, an adhesion promoter in order to improve its adhesion on the plastic material layer and thus increase its tear resistance, and/or a slip agent (such as precipitated, pyrogenic or colloidal silica, or polyethylene, PTFE or polypropylene waxes, for example).

The matte varnish layer may, however, not contain this slip agent, which enables its abrasion and scratch resistance to be reinforced.

The matte varnish layer can also be coloured, and the colouring of said layer is simple and the number of colours available for this layer is almost infinite. Finally, as the deposition of the matte varnish layer on the plastic material layer is performed by coating, the production of the sheet according to the invention may require a single bonding operation, that of bonding of the metallic layer on the support layer, which is more economical than the prior art in which the two bonding operations are necessary.

In this application, the term coating refers to a technique consisting of applying a liquid or semi-liquid solution, in a solvent, aqueous or other phase, on the surface of a substrate, and this application can be followed by a step of hardening by drying or even a cross-linking step if the solution is polymerizable. This coating is preferably self-controlled so that the solution is applied with a constant determined thickness on the substrate. The solution is advantageously deposited in a thin layer with a thickness of between 0.1 and 30 μm, preferably between 0.2 and 5 μm, and, for example, between 0.5 and 2 μm. The coating can be performed by a roller printing technique, for example by heliogravure, flexography or by an offset process or by air blade, curtain or metal blade coating processes.

The matte varnish layer is also transparent or translucent (like the plastic material layer), which means that an observer can see through said layer (and the plastic material layer). The observer can thus see or distinguish the metallic layer through the matte varnish layer and the plastic layer of the sheet according to the invention, and can thus appreciate the visual depth effect and the iridescent appearance of the sheet, as well as both the metalized and matte appearance of said sheet.

The plastic material layer of the sheet according to the invention can include a plastic film, a sub-layer of a coloured varnish coating, and/or a primer sub-layer. It can also include a plurality of plastic films and/or a plurality of sub-layers of the aforementioned types.

The matte varnish layer is advantageously deposited on a primer sub-layer of the plastic material layer, in which said primer sub-layer can be deposited by coating on a plastic film or a coloured varnish sub-layer.

This primer sub-layer confers anti-scratch and abrasion resistance properties on the sheet according to the invention. It indeed makes it possible to notably reinforce the resistance of the matte varnish layer to tearing and therefore limits the risk of appearance of “glossy” and “metallic” scratches, as explained above. It can form an adhesion primer.

The primer sub-layer can be deposited by coating in an amount of 0.1 to 3 g/m², preferably 0.5 to 2 g/m² and for example 1 g/m². It has a low thickness, which is between 0.1 and 3 μm. This primer sub-layer can be based on acrylic, polyurethane, vinyl acetate, styrene butadiene, polyamide, polyester, silane and polysiloxane polymers, polyamide, cellulose derivative, vinyl polychloride, polymers based on urea and aldehyde, and mixtures of same.

The deposition of this primer sub-layer can be performed by the same coating technique as used for the deposition of the matte varnish layer, or by any other coating technique.

The plastic film of the plastic material layer can be synthetic or natural and be, for example, fossil or plant based, or it can be obtained by recycling. It can be colourless or vat-dyed. In particular, it has a thickness of between 1 and 1000 μm, preferably between 4 and 200 μm, and, for example, between 8 and 50 μm. In a particular example of an embodiment of the invention, the plastic film has a thickness of around 12 or 23 μm. The plastic film is, for example, a polyethylene terephthalate (PET), polyethylene (PE), polypropylene (PP), polylactic acid-based polymer (PLA) film or a film of any other cellulose-based polymer. Other transparent or translucent plastic materials may however be suitable.

The plastic film can be coated (at least partially) on at least one of its faces with a coloured varnish coating sub-layer. Alternatively, or as a complementary feature, a coloured varnish coating sub-layer can at least partially cover the upper face of the metallic layer.

The coloured varnish can be of the nitrocellulose, polyester, polyurethane, acrylic, cellulosic, vinyl, polyamide or other type. The plastic material layer can include one or more coloured varnish coating sub-layers. The deposition of the coloured varnish can be performed by the same coating technique as used for the deposition of the matte varnish layer, or by any other coating technique.

This coloured varnish is advantageously deposited in a thin layer with a thickness of between 0.1 and 30 μm, preferably between 0.5 and 10 μm, and, for example, between 1 and 4 μm. It can be deposited in an amount of 0.1 to 30 g/m², preferably 0.5 to 10 g/m² and, for example, 1 to 4 g/m². It can include fillers such as pigment dyes, titanium dioxide or nacreous pigments such as Iriodin® sold by the MERCK company. It can also include an adhesion promoter to improve its adhesion on the plastic film or on the metallic layer.

The metallic or reflective layer can be formed by one or more metallic films. Alternatively, or as a complementary feature, at least some of a lower face of the plastic material layer is covered by a metallic deposit, for example by vacuum metallization or by printing or coating with metallic ink.

In this application, a metallic film, which can be pre-formed, then fixed to a surface of a substrate, for example by bonding, is distinguished from a metallic deposit, which is formed directly on a surface of a substrate.

The metallic layer of the sheet according to the invention can include aluminium, silver, chromium, tin, a metal oxide, and so on, or consist of one of these components or a mixture of these components.

The thickness of the metallic layer can be between 1 nm and 1000 nm, for example between 1 nm and 500 nm, preferably between 10 nm and 100 nm, and more preferably between 10 nm and 50 nm. In a particular example of an embodiment of the invention, the metallic layer is formed by an aluminium sheet with a thickness of several microns, and, for example, around 6 μm. In another example of an embodiment, the metallic layer is formed by a deposition of several nanometres or dozens of nanometres in thickness, and for example around 20 nm in thickness.

The lower support layer can include at least one paper, cardboard, plastic film or any substrate in sheet form such as leather or a woven or nonwoven textile. The paper can be of any type (fine, thin, tracing, and so on). The plastic film can, for example, be made of polypropylene or polyethylene. This lower layer is preferably deformable and in particular foldable in order to allow the finished product, the multilayer sheet, to be fashioned.

If the support layer is a paper, it can have a basis weight of between 60 and 500 g/m², and for example between 200 and 300 g/m². It can be, for example, a textured paper (such as Velin Arches® paper 300 g/m² sold by the Arjowiggins company) or a coated paper, for example on chromium (such as the Chromolux® paper 250 g/m² sold by the Zanders company). This paper can be smooth or rough.

The materials of the multilayer sheet according to the invention are advantageously chosen so as to be capable of withstanding relatively significant mechanical and/or thermal stresses during sheet fashioning and printing operations. The sheet according to the invention is particularly suitable for undergoing folding, plating and other operations.

The sheet according to the invention can consist of a lower support layer, an intermediate metallic layer, an upper transparent or translucent plastic material layer, and a transparent or translucent matte varnish coating over-layer as defined in the present application. This varnish preferably has a soft or silky touch. The plastic material layer can consist of a plastic film and a coloured varnish sub-layer, a plastic film and a primer sub-layer, or a plastic film and two sub-layers, of coloured varnish and primer, respectively.

The invention also relates to a method for producing a multilayer sheet as described above, characterized in that it includes the steps consisting of:

a) applying, on a lower face of the plastic material layer, a metallic deposit, or bonding the plastic material layer to a metallic film,

b) coating the upper face of the plastic material layer with a matte varnish layer, in which step (b) is performed before or after step (a), then:

c) bonding a lower face of the metallic layer to an upper face of the support layer.

The upper face of the plastic material layer can be coated in step (b) with the matte varnish layer by a printing technique, and, for example, heliogravure, as seen above. The upper face of the plastic material layer can also be covered in step (a) with the metallic deposit by vacuum metallisation or by printing or coating with metallic ink, as described above.

When the plastic material layer includes a plastic film and a coloured varnish, the method preferably includes, before step (a), a step consisting of depositing by coating a sub-layer of said coloured varnish on a face of the plastic film or on an upper face of the metallic film.

Advantageously, when the plastic material layer includes a plastic film and a primer sub-layer, the method includes, before step (b), a step consisting of depositing by coating said primer sub-layer on the upper face of the plastic film.

The method can also include a step consisting of subjecting the plastic film to a corona effect treatment. This treatment consists of ionization of oxygen molecules at the surface of the film under the effect of a powerful electrical field. This has the effect of reinforcing the adhesion of the matte varnish layer on the plastic film.

The method can also include, after step (b), a step consisting of causing the cross-linking of the matte varnish layer in order to reinforce its abrasion resistance, as explained above.

The invention can be better understood and other details, features and advantages of this invention will be clearer in view of the following description, provided as a non-limiting example, in reference to the appended drawings, in which:

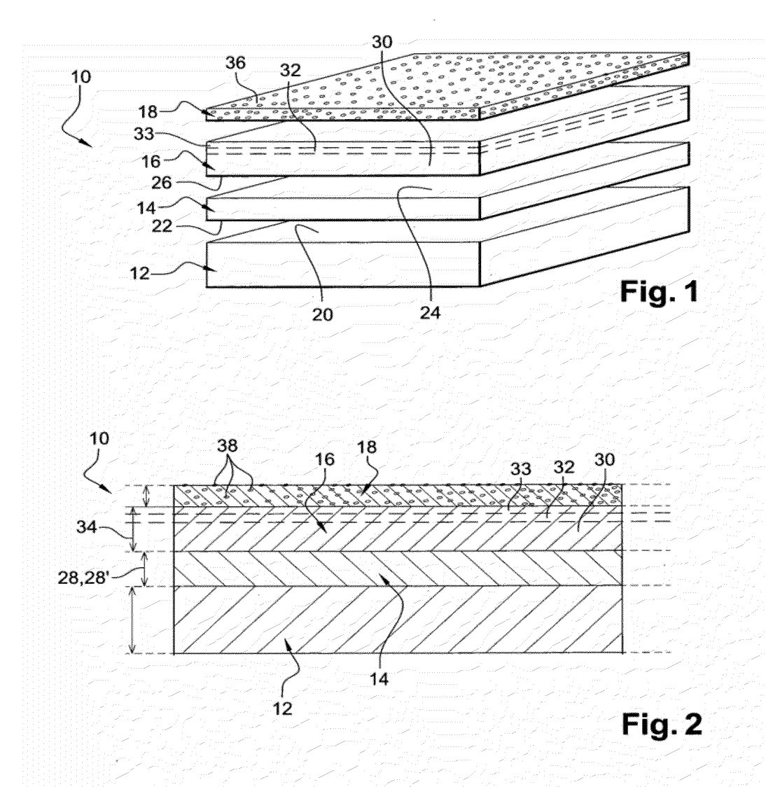

FIG. 1 is a diagrammatic exploded perspective view of a printable sheet according to the invention,

FIG. 2 is a diagrammatic cross-section view of the sheet of FIG. 1,

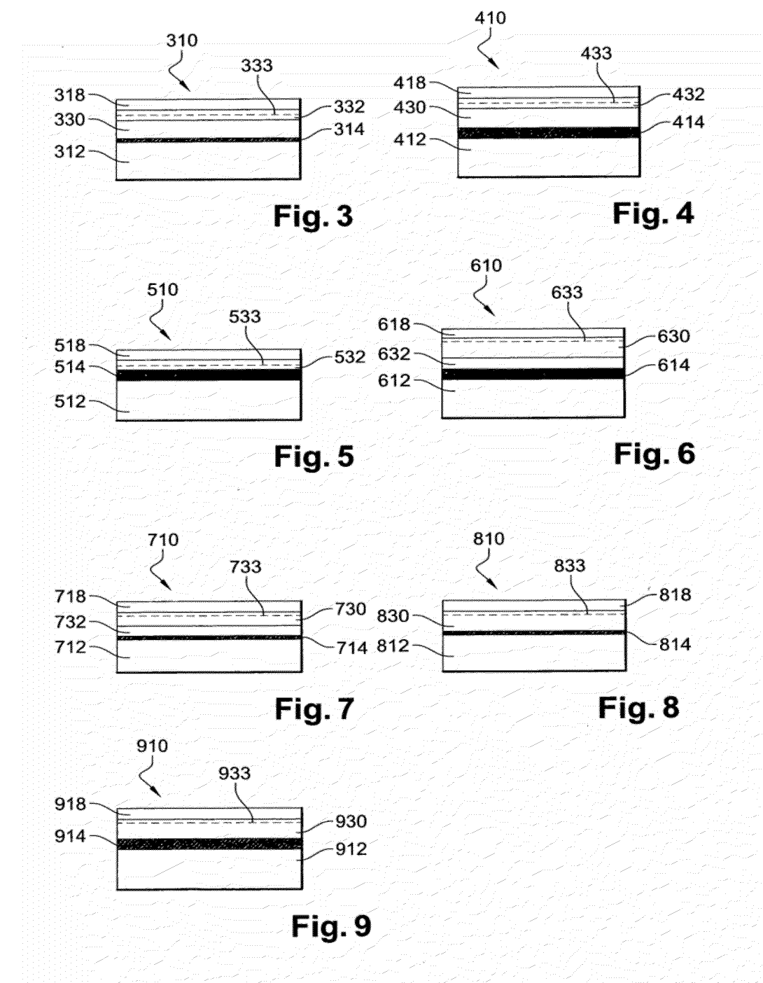

FIGS. 3 to 9 are diagrammatic views of alternative embodiments of the sheet according to the invention,

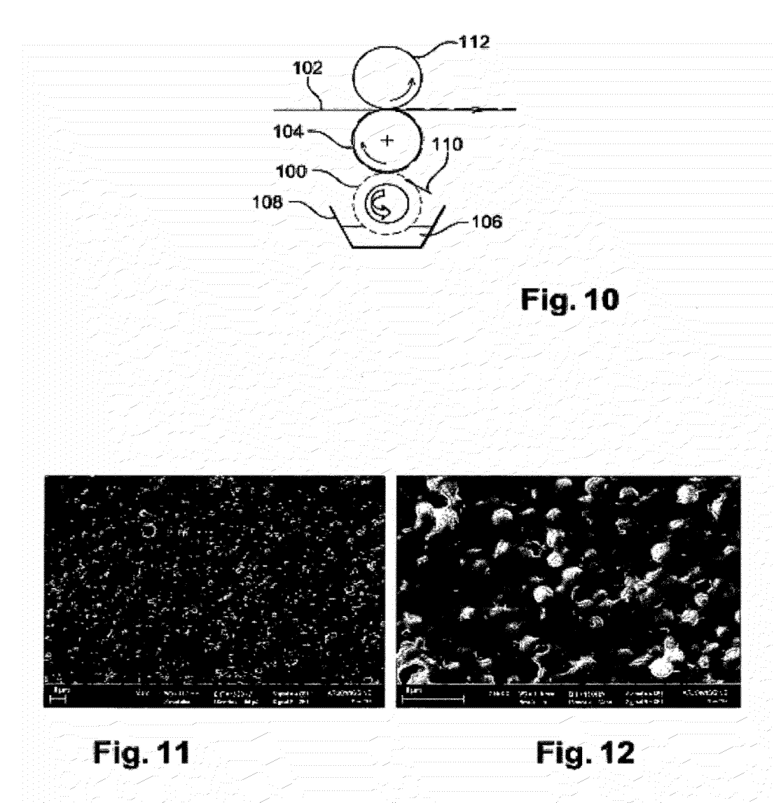

FIG. 10 is a diagrammatic view of a device for coating a sheet and shows a step of the method of production according to the invention,

FIGS. 11 and 12 are scanning electron microscopy (SEM) images of the upper face of the matte varnish layer of a sheet according to the invention, in which the enlargements are respectively x500 and x2000,

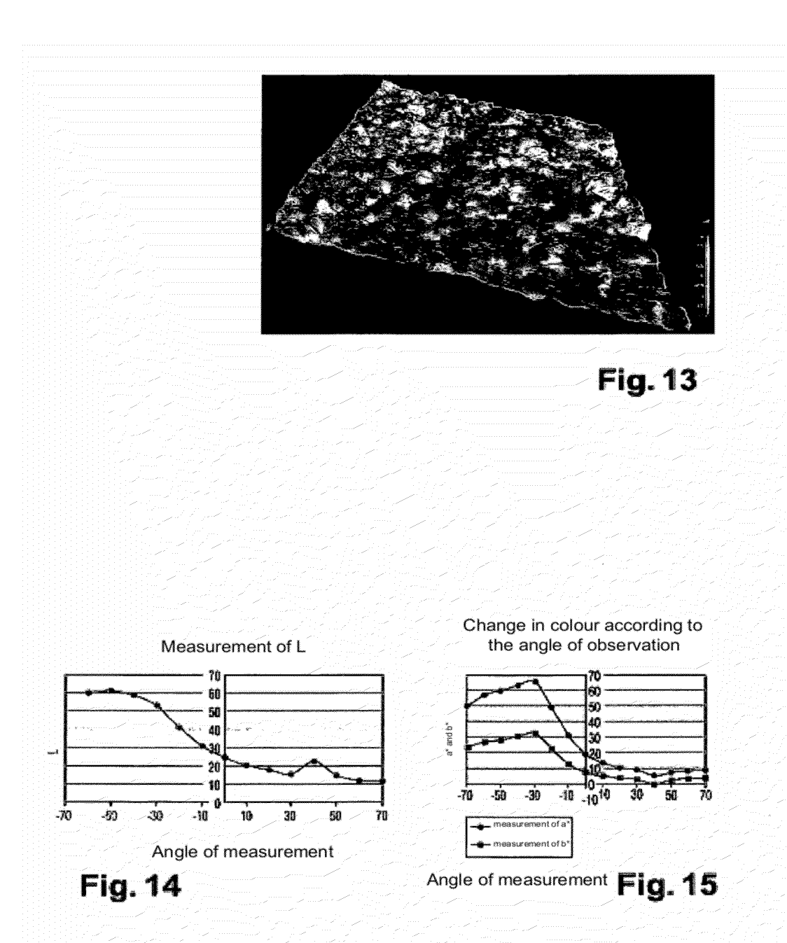

FIG. 13 is an image showing the surface topography of the matte varnish layer of the sheet of FIGS. 11 and 12, and

FIGS. 14 and 15 are graphs showing the variation in colour of the sheet of FIGS. 11 and 12, according to the angle of observation of said sheet, in a system L, a*, b*.

Reference is first made to FIGS. 1 and 2, which show a multilayer sheet 10 according to the invention, i.e. a sheet comprising a plurality of layers superimposed one on another, in which said sheet is advantageously printable and, for example, capable of being used in the field of packaging of food products or cosmetic products such as a perfume.

This sheet 10 essentially comprises four layers or strata: a lower support layer 12, an intermediate metallic layer 14 on the support layer 12, an upper plastic material layer 16 on the metallic layer 14, and an over-layer 18 of a matte varnish, preferably having a soft or silky touch on the plastic material layer 16.

The metallic layer 14 confers on the sheet a metallic and glossy appearance, and the plastic material layer 12, which is transparent or translucent, confers on it a visual depth effect and an iridescent appearance when it is coloured. The varnish over-layer 18 is matte and transparent or translucent, which, in combination with the metallic appearance of the metallic layer, produces a highly aesthetic visual effect reinforced by the depth effect and the iridescent appearance mentioned above. The free upper face of the matte varnish over-layer 18 is also preferably soft to the touch. The sheet according to the invention can therefore be both agreeable to touch and to see.

The different layers of the sheet according to the invention, and in particular their compositions and characteristics, will be described in greater detail below.

The lower support layer 12 can be formed by a paper, cardboard, plastic film or any substrate in fibrous or non-fibrous sheet form, such as leather, a woven or nonwoven textile, and so on. This lower layer 12 is preferably deformable and in particular foldable so as to allow the finished product, the sheet 10, to be fashioned.

The following papers can, for example, be used as support layers 12: Chromolux® 250 g/mm² sold by the Zanders company, and Maine Gloss® 250 g/mm², Conqueror Wove® 240 g/mm², Conqueror Laid® 240 g/mm² and Velin Arches® 300 g/mm² sold by the Arjowiggins company.

The upper face 20 of the support layer 12 is bonded by means of a solvent-based or aqueous-based adhesive on the lower face 22 of the metallic layer 14. Numerous types of adhesive can be used, such as, for example, polyurethane-based adhesives.

The metallic layer 14 can be formed by a metallic film or a metallic deposit including or consisting, for example, of aluminium, silver, chromium, tin, a metal oxide, and so on, or a mixture of compounds of the latter.

When the metallic layer 14 is a metallic deposit, this deposit is formed on the lower face 26 of the plastic material layer 16, by means of a well-known technique of vacuum metallization or coating or printing with metallic ink. This metallic deposit can have a thickness 28 on the order of around 20 nm.

When the metallic layer 14 is a metallic film, the upper face 24 of said film is bonded to the lower face 26 of the plastic layer 16 or the plastic layer is deposited (by coating) on the upper face 24 of the metallic film. The metallic film can have a thickness 28′ on the order of around 6 μm.

The adhesive used to bond the plastic material layer 16 to the metallic film 14 can be identical to or different from that used to bond the metallic film to the upper face 20 of the support layer 12.

The plastic material layer 16 can include a plastic film 30, a coloured varnish coating sub-layer 32, which is different from the aforementioned matte varnish, and/or a primer sub-layer 33, which is intended to improve the adhesion of the over-layer 18 and prevent or at least limit the tearing thereof.

The coating sub-layer 32 can be located between the plastic film 30 and the metallic layer 14, between the over-layer 18 of the matte varnish and the plastic film 30, or between the primer sub-layer 33 and the plastic film 18, as is the case in the example shown.

The primer sub-layer 33 is always located directly below the matte varnish over-layer 18 and can be deposited by coating on the upper face of the plastic film 30 or the coloured varnish sub-layer 32, as is the case in the example shown.

The plastic film 30, the coating sub-layer 32 and the primer sub-layer 33 are made of transparent or translucent materials so that an observer can distinguish or see the metallic layer 14 through them.

As seen above, the lower face 28 of the plastic film 30 can be bonded to the upper face 24 of the metallic film or can be coated directly by a metallic deposit. The upper face of the plastic film can be covered by the coating sub-layer 32 of the varnish, or directly by the over-layer 18 of the matte varnish when the plastic layer 16 does not comprise sub-layers 32, 33.

Alternatively, the coating sub-layer 32 is deposited on the upper face 24 of a metallic film 14, then the upper face of said layer is bonded to the lower face 28 of the plastic film 30, or is covered by the over-layer 18 of the matte varnish when the plastic layer 16 does not comprise a film 30. A primer sub-layer 33 can be inserted between the sub-layer 32 and the over-layer 18.

The adhesive used to bond the coating sub-layer 32 on the plastic film 30 can be the same as that mentioned above, or a different adhesive.

The plastic material layer 16 has a thickness 34 of between 1 and 1000 μm, preferably between 4 and 200 μm, and, for example, between 10 and 50 μm.

The coating sub-layer 32 can, for example, be formed by a polyester, a polyurethane, a polyamide, or it can be an acrylic, vinyl, cellulosic, nitrocellulosic polymer and so on. The plastic film can be a polyethylene terephthalate (PET), polyethylene (PE), polypropylene (PP), polylactic acid-based polymer (PLA) film or a film of any other cellulose-based polymer.

The plastic film 30 and/or the coating sub-layer 32 can be coloured or tinted. The colour of the coating sub-layer 32 can be obtained by adding dyes and/or pigments. The coating sub-layer 32 can also include filers such as calcium carbonate, silica, titanium dioxide, nacreous pigments and/or an adhesion promoter based on polyester, polysiloxane or any other polymer improving adhesion such as BYK 4510 sold by the BYK Chimie company or Laropal A81 of the BASF company.

The primer sub-layer 33 can be based on polymers such as polyester, polysiloxane, acrylic, polyurethane, vinyl acetate, epoxy or any other polymer having good adhesion to the plastic film.

The matte varnish over-layer 18 is deposited by coating on the upper face of the plastic layer 16, i.e. on the upper face of the plastic film 30, the coating sub-layer 32 or the primer sub-layer 33, as in the example shown.

The matte varnish layer and, as the case may be, the sub-layers of the plastic material layer 16 are advantageously deposited by a roller coating technique called heliogravure, which will be described in greater detail below in reference to FIG. 10. Other roller coating techniques can nevertheless be used for the deposition of these products, such as offset, flexography, serigraphy or air blade, curtain, trailing blade or scraping coating processes can also be used.

The upper face 36 of the matte varnish is preferably in relief so that it has an agreeable soft or silky touch. This relief is obtained by low-amplitude surface irregularities, i.e. the face 36 is neither perfectly smooth nor rough.

The surface irregularities can be obtained by pigments 38 contained in the over-layer 18 and of which at least some project on the upper face of said over-layer. In this case, the over-layer includes a binder in addition to said pigments 38.

The pigments 38 can be polyurethane, polypropylene acrylic or silica beads and the binder can be based on polyurethane, acrylic, PMMA, nitrocellulose or any other cellulose, or a mixture of the above.

The relief of the upper face 36 of the over-layer 18 is formed by bumps and recesses, in which the distance between the base of the recesses and the top of the bumps may be less than or equal to around 3 μm, and, for example, on the order of around 2 μm, as will be described in detail below in reference to FIGS. 11 to 13.

The matte varnish over-layer 18 can also be coloured, in which the colour can be obtained by adding dye, pigments, nacreous pigments or any other product changing the colour of the varnish. As seen above, the plastic material layer 16 (i.e. the plastic film 30, the coating sub-layer 32 and/or the primer sub-layer 33) can also be coloured, which makes it possible to obtain a large choice of colours for the sheet.

The matte varnish over-layer 18 can also include a cross-linking agent, a slip agent, and/or an adhesion promoter. The cross-linking agent is, for example, based on Aziridine, polyamine, epichlorohydrin amide, or zirconium or aldehyde salts. The slip agent can be precipitated, pyrogenic or colloidal silica or polyethylene or polypropylene waxes, and the adhesion promoter can be a polyolefin polymer, for example.

The following products can be used as a matte varnish in the sheet according to the invention: precipitated, pyrogenic or colloidal silicas, or polyurethane or acrylic beads.

FIGS. 3 to 9 show alternative embodiments of the multilayer sheet according to the invention.

The sheet 310 of FIG. 3 includes a support layer 312 on which a plastic film is bonded 330, of which the lower face is covered by a metallic deposit 314 and the upper face is covered by a coloured varnish coating layer 332. An over-layer 318 of a matte varnish having a soft or silky touch covers the upper face of the coating sub-layer 332 or a primer sub-layer 333 deposited on the coating sub-layer 332. The production of this sheet 310 requires a single bonding or counter-bonding operation.

The sheet 410 of FIG. 4 differs from that of FIG. 3 in that the metallic layer is formed by a metallic film 414. The upper face of this film 414 is bonded to the lower face of the plastic film 430 and its lower face is bonded to the support layer 412. As in the case of FIG. 3, the coloured varnish sub-layer 432 is deposited by coating on the plastic film 430 and the matte varnish over-layer 418 is then deposited by coating on the sub-layer 432 or a primer sub-layer 433 deposited on the sub-layer 432.

The sheet 510 of FIG. 5 differs from that of FIG. 4 in that it does not have a plastic film. The plastic material layer of this sheet is then formed by a coating sub-layer 532 of the coloured varnish and optionally by a primer sub-layer 533, which are inserted between the matte varnish over-layer 518 and the metallic sheet 514, which is itself bonded to the support layer 512.

The sheet 610 of FIG. 6 differs from that of FIG. 4 in that the positions of the plastic film 630 and the coloured varnish sub-layer 632 have been inverted. The sub-layer 632 is deposited by coating on the upper face of the metallic sheet 614 of which the lower face is bonded to the support sub-layer 612. The lower face of the plastic film 630 is bonded to the upper face of the layer 632, and its upper face is covered by coating of the matte varnish over-layer 618 or the primer sub-layer 633 on which the over-layer 618 is deposited.

The sheet 710 of FIG. 7 differs from that of FIG. 6 in that the metallic layer is formed by a metallic deposit 714 formed on the lower face of the coating sub-layer 732 previously deposited on the lower face of the plastic film 730, which receives, on its upper face, a matte varnish over-layer 718, and optionally a primer sub-layer 733. The assembly is bonded to the support layer 712.

The sheet 810 of FIG. 8 differs from that of FIG. 3 in that it does not have a coloured varnish sub-layer. The matte varnish over-layer 818 is deposited on the upper face of the plastic film 830 or on a primer sub-layer 833 deposited on said upper face of the plastic film. The lower face of the plastic film 830 is covered with a metallic deposit 814, which is then bonded to the support layer 812.

Similarly, the sheet 910 of FIG. 9 differs from that of FIG. 4 in that it does not have a coloured varnish sub-layer. The matte varnish over-layer 918 is deposited on the upper face of the plastic film 930 or on a primer sub-layer 933, which is itself deposited on the upper face of the plastic film. The lower face of the plastic film is bonded to the upper face of the metallic film 914. The lower face of this metallic film 914 is bonded to the support layer 912.

In another alternative not shown, the matte varnish layer of FIGS. 3-9 may be replaced by a film covered with a matte varnish layer. In this case, the film would act as a support for the matte varnish layer.

The different layers of the sheet according to the invention can be applied to the support paper by classic paper coating means, for example curtain, air blade, heliogravure or flexo-gravure processes. These layers can be deposited in a single passage by a multilayer curtain process, for example.

FIG. 10 shows a step of producing a sheet according to the invention, which is the deposition of a liquid solution coating layer (matte varnish, coloured varnish, and/or primer) on a substrate (which is the plastic layer in the case of the matte varnish, the plastic film of the plastic material layer or the metallic layer in the case of the coloured varnish, and the plastic film or the coloured varnish sub-layer in the case of the primer) by a printing technique called heliogravure.

Heliogravure is a roller printing technique in which a liquid solution 106 is transferred from a multi-perforated roller 100 to a sheet substrate 102 by means of an application roller 104.

The external cylindrical surface of the roller 104 is etched by laser or by means of a diamond, for example in order to carve cells for receiving the solution 106. The shape and sizes of these cells determine the amount of liquid solution to be deposited on the substrate 102.

The roller 100 rotates about its axis of rotation in a container 108 containing the liquid solution 106. A blade 110 is flush with the external surface of the roller 100 so as to remove the excess solution on it.

The solution 106 is transferred from the multi-perforated roller 100 to the application roller 104, then to the substrate 102, which is applied to the application roller by means of a counter-roller 112.

Examples of embodiments of a sheet according to the invention will now be described below.

### EXAMPLE 1

### Production of a Red-Coloured Multilayer Sheet

A printable multilayer sheet of the type shown in FIG. 7 (without the primer sub-layer 733) was produced from a Main Gloss® 250 g/m² paper of the Arjowiggins company as a lower support layer, an aluminium deposit with a thickness of 20 nm as a metallic layer, a red-coloured varnish having a thickness of 3 μm, a PET film with a thickness of 12 μm as a plastic layer, and a matte varnish having the following composition:
33% by weight of polyurethane microbeads of which the average diameter is around 4 μm (sold by the Dainishiseika company under the name Daiplacoat®),
0.3% by weight of precipitated silica particles (acting as a slip agent) with an average diameter of 5 μm (sold by the Grace Division company under the name Siloïd®), and
66.7% by weight of a binder based on a mixture of polyurethane and acrylic sold by the Lamberti company under the name Rolflex PAD®).

The amount of binder with respect to pigment is close to 200% by weight, and the binder has an elongation rate greater than 500%.

The lower face of the PET film was first covered by a red varnish coating layer, in an amount of 3 to 4 g/m², by heliogravure. After drying, this film is vacuum-metallised on its already-varnished face. The upper face of the film is covered by heliogravure of a matte varnish coating layer, in an amount of 1.5 to 2 g/m². The assembly obtained is then bonded by means of a solvent-based adhesive to the Main Gloss® paper in order to obtain, after drying of the adhesive, a multilayer printable sheet according to the invention with a red colour.

### EXAMPLE 2

### Production of a Multilayer Sheet of the Type of Example 1, with, in Addition, a Primer Sub-Layer

Another multilayer printable sheet of the type of FIG. 7 (with the primer sub-layer 733) was prepared with the same products as used in example 1, with the exception of the support layer, which is in this case formed by a Main Gloss® 300 g/m² paper. The primer sub-layer is provided by the Luminescence Inc. company, under reference 10843X or 11035G. It is deposited in an amount of around 1 g/m² on the upper face of the PET film, which is in this case pre-treated acrylic.

### EXAMPLE 3

### Production of a Multilayer Sheet of the Type of Example 1, with, in Addition, a Cross-Linking Agent in the Matte Varnish Over-Layer

The matte varnish over-layer includes, in addition to the products listed in example 1, a cross-linking agent based on Aziridine, sold by the DSM Neoresin company, under the name CX1000.

### EXAMPLE 4

### Production of a Multilayer Sheet of the Type of Example 1, with, in Addition, an Adhesion Promoter in the Matte Varnish Over-Layer

The matte varnish over-layer includes, in addition to the elements listed in example 1, a BYK 4500 adhesion promoter, sold by the BYK Chimie company.

### EXAMPLE 5

### Production of a Multilayer Sheet of the Type of Example 1, with, in Addition, an Adhesion Promoter in the Coloured Varnish Sub-Layer

The coloured varnish sub-layer of example 1 includes, in this case, in addition, the adhesion promoter of example 5.

### EXAMPLE 6

### Corona Effect Treatment of a Multilayer Sheet Obtained in Example 1

A PET film with a thickness of 12 μm is treated by corona effect, then this film is used to produce a sheet of the type of example 1.

### EXAMPLE 7

### Production of a Multilayer Sheet of the Type of Example 1, without a Slip Agent in the Matte Varnish Over-Layer

A new sheet is produced from the products of example 1, with the exception of the matte varnish over-layer, which does not have a slip agent (precipitated silica).

### EXAMPLE 8

### Production of Another Multilayer Sheet of the Type of FIG. 3

A printable multilayer sheet of the type of FIG. 3 (without the primer layer 333) was produced with the same products as those of example 1.

### Results of the Abrasion Tests of the Sheets Obtained in Examples 1 to 8

Abrasion tests were performed with a Washability® apparatus of Braive Instrument on the sheets obtained in examples 1 to 8 above. Each sheet to be tested is intended to rob on itself with a weight of 1 kg, which is placed on a 30-cm² surface of the sheet, and which is moved on the sheet in an amount of 40 back-and-forth cycles, at a rate of 1 cycle every 3 seconds.

The results are evaluated by counting the number of significant scratches (visible to the naked eye) on the areas of movement of the weight on the sheet, and by distinguishing the glossy scratches showing the plastic material layer of the sheet and the metallic scratches showing the metallic layer of the sheet.

The table below shows the results of these tests.

| | Number of | Number of | |
|---|---|---|---|
| | glossy | metallic | |
| Sheet tested | scratches | scratches | Observations |
| Example 1: | 58 | 0 | Ø |
| sheet of | | | |
| FIG. 7 | | | |
| without a | | | |
| primer layer | | | |
| and with a | | | |
| slip agent in | | | |
| the matte | | | |
| varnish over- | | | |
| layer | | | |
| Example 2: | 1 | 0 | Ø |
| sheet of | | | |
| example 1 | | | |
| with a primer | | | |
| layer in the | | | |
| matte varnish | | | |
| over-layer | | | |
| Example 3: | 3 | 0 | Very visible |
| sheet of | | | scratches |
| example 1 | | | |
| with a cross- | | | |
| linking agent | | | |
| in the matte | | | |
| varnish over- | | | |
| layer | | | |
| Example 4: | 55 | 0 | Ø |
| sheet of | | | |
| example 1 | | | |
| with an | | | |
| adhesion | | | |
| promoter in | | | |
| the matte | | | |
| varnish over- | | | |
| layer | | | |
| Example 5: | 33 | 6 | Very visible |
| sheet of | | | scratches |
| example 1 | | | |
| with an | | | |
| adhesion | | | |
| promoter in | | | |
| the coloured | | | |
| varnish sub- | | | |
| layer | | | |
| Example 6: | 37 | 0 | Ø |
| sheet of | | | |
| example 1 | | | |
| treated by | | | |
| corona effect | | | |
| Example 7: | 6 | 0 | Ø |
| sheet of | | | |
| example 1 | | | |
| without the | | | |
| slip agent in | | | |
| the matte | | | |
| varnish over- | | | |
| layer | | | |
| Example 8: | 32 | 7 | Very visible |
| sheet of | | | scratches |
| FIG. 3 | | | |
| without a | | | |
| primer layer | | | |

The number of glossy scratches of the sheet obtained in example 8 is lower than that of the sheet obtained in example 1. The fact that the matte varnish over-layer is deposited on the coloured varnish sub-layer (and not on the plastic film) therefore makes it possible to improve the adhesion and attachment of said over-layer on the sheet. However, metallic scratches appear on the sheet of example 8, which are very visible. In spite of the relatively high number of glossy scratches on the sheet of example 1, this sheet is preferable to that of example 8 because it is free of metallic scratches.

The corona effect treatment, which improves the attachment of the matte varnish over-layer of the sheet (example 6) provides positive results.

The cross-linking of the matte varnish over-layer is also a beneficial option since the scratches have practically disappeared. However, the remaining scratches are very visible (example 3).

The removal of the slip agent of the composition of the matte varnish over-layer is positive with regard to the results obtained. However, the slip agent remains, in some cases, essential during the production of the sheet (example 7).

The addition of an adhesion promoter in the matte varnish over-layer (example 4) or in the coloured varnish sub-layer (example 5) did not give positive results.

The best results were obtained with the sheet of example 2, i.e. by using a primer sub-layer to improve the adhesion of the matte varnish over-layer on the sheet. This makes it possible to very clearly limit the risks off tearing of said over-layer, as only one glossy scratch was observed in the tests.

### Results of Additional Tests Performed on the Sheet Obtained in Example 2

The dynamic friction coefficient of the sheet obtained in example 2 was measured according to standard NF-Q-03-082 with a 200-g slide, and is 0.52. It is high enough to have a significant touch (>0.3) and low enough (<0.8) not to present any problems of machinability of the sheets on the printing or converting machines.

FIGS. 11 and 12 are images produced by means of a Zeiss EV050 scanning electron microscope of the upper face of the matte varnish over-layer of the sheet of example 2. The enlargement of FIG. 11 is x250 and that of FIG. 12 is x2000.

The polyurethane microbeads are distributed randomly in the matte varnish over-layer and define low-amplitude surface irregularities conferring a particular soft or silky touch on the sheet.

FIG. 13 is a surface topography of the upper face of said matte varnish over-layer, produced by means of an Altisurf 500. It shows the particular relief of said upper face, which is formed by bumps and recesses. The average roughness, i.e. the distance between the base of the recesses and the top of the bumps is equal to around 3 μm, which corresponds substantially to the average diameter of the polyurethane beads. This roughness makes it possible to have a product that is both smooth and soft to the touch and with a silky appearance.

The sheet of example 2 was also subjected to tests for measuring the colour variation according to the angle of observation of the sheet in a system L, a*, b*, owing to a spectrophoto-goniometer of the SPC company. This makes it possible to identify the optical “colour path” properties of the sheet according to the invention.

FIG. 14 is a graph showing the variation in the parameter L according to the angle of observation of the sheet, and FIG. 15 is a graph showing the variation in parameters a* and b* according to this angle of observation.

The colour of the sheet varies from an intense and luminous red for an angle of observation of −70° C. to an almost-black colour for an angle of observation of +70° C.

The sheet of example 2 was subjected to a plurality of tests in order to verify its behaviour in fashioning and various printing techniques. The sheet was printed by an offset method using a Roland 4 colour press with Novaplast drier inks. Very good results and printing outputs were obtained. The sheet was subjected to a Wickert hot-plating with a Luxor AB220 plating film of the Kurz company, and a very good adhesion of the plating film on the matte varnish was observed. The sheet also received an embossment (with an industrial embosser) with high definition. The sheet was subjected to a plurality of foldings (by means of a Bernard folder) and did not show any rupture or breakage of the layers at the folds.

The sheet according to the invention has numerous advantages listed below:
the sheet can be produced by means of a single bonding or counter-bonding operation, which limits the production cost of said sheet; this is the case, for example, when the matte varnish over-layer and the plastic and metallic layers are secured to one another without adhesive and only the metallic layer is bonded to the support layer,
the colour of the sheet is not limited by the colours available for the plastic film of the plastic material layer because each varnish layer or sub-layer can easily be coloured; it is therefore possible to envisage producing sheets of a particular colour at low cost, without a significant additional cost,
the sheet can optionally have a plurality of colours, in which said colours can be very bright or very dark,
the sheet has a very soft or silky touch owing in particular to the surface characteristics of the matte varnish over-layer,
the sheet is opaque, and can therefore be used to produce envelopes, for example, and
the sheet has very good folding, embossing, plating, printing behaviours, and so on.

1. Multilayer sheet, including a lower support layer, an intermediate metallic or reflective layer and an upper transparent or translucent plastic material layer, wherein at least a portion of an upper face of the plastic material layer is covered by a coating layer of a transparent or translucent matte varnish.

2. Sheet according to claim 1, wherein the matte varnish layer includes an upper face with surface irregularities so as to confer on the sheet a soft or silky touch.

3. Sheet according to claim 2, wherein the layer of plastic material includes a primer sub-layer deposited by coating and in that the matte varnish layer covers at least a portion of an upper face of said primer layer.

4. Sheet according to claim 3, wherein the primer sub-layer is deposited in an amount of 0.1 to 3 g/m².

5. Sheet according to claim 1, characterized in wherein the plastic material layer includes a plastic film.

6. Sheet according to claim 5, wherein at least a portion of a face of the plastic film or an upper face of the metallic layer is covered by a coating sub-layer of a coloured varnish.

7. Sheet according to claim 1, wherein the plastic material layer includes a coating sub-layer of a coloured varnish.

8. Sheet according to claim 7, wherein at least a portion of an upper face of the metallic layer is covered by the coating sub-layer of the coloured varnish.

9. Sheet according to claim 6, wherein the coating sub-layer of the coloured varnish includes filers and/or an adhesion promoter.

10. Sheet according to claim 1, wherein the metallic or reflective layer is formed by a metallic sheet.

11. Sheet according to claim 1, wherein the metallic or reflective layer is formed by a metallic deposit covering at least a portion of a lower face of the plastic material layer.

12. Sheet according to claim 1, wherein the lower support layer includes a paper, cardboard, plastic film or fabric.

13. Sheet according to claim 1, wherein the matte varnish layer is coloured and/or cross-linked.

14. Sheet according to claim 1, wherein the matte varnish layer includes an adhesion promoter and/or a slip agent.

15. Sheet according to claim 1, wherein the matte varnish layer includes pigments and a binder, and at least some of these pigments are intended to project on the upper surface of said layer so as to define a soft or silky feel.

16. Sheet according to claim 15, wherein the pigments have an average diameter of less than 10 μm.

17. Sheet according to claim 15, wherein the pigments define a relief formed by bumps and recesses on the upper face of the matte varnish layer.

18. Sheet according to claim 1, wherein the upper face has a dynamic friction coefficient measured according to standard NF-Q-03-082, of between 0.3 and 0.8 and.

19. Method for producing a multilayer sheet according to claim 1, wherein it includes the steps consisting of:
a) applying, on a lower face of the plastic material layer, a metallic ink or deposit, or bonding the plastic material layer to a metallic film,
b) coating the upper face of the plastic material layer with a matte varnish layer, in which step (b) is performed before or after step (a), then:
c) bonding a lower face of the metallic layer to an upper face of the support layer.

20. Method according to claim 19, wherein, in step (b), the upper face of the plastic material layer is coated with a matte varnish layer by a printing or coating technique.

21. Method according to claim 19, wherein, in step (a), the lower face of the plastic material layer is covered by the metallic deposit by vacuum metallization or by printing or coating with metallic ink.

22. Method according to claim 19, wherein, if the plastic material layer includes a plastic film and a coloured varnish, the method includes, before step (a), a step consisting of depositing by coating a sub-layer of said coloured varnish on a face of the plastic film or on an upper face of the metallic film.

23. Method according to claim 19, wherein, if the plastic material layer includes a plastic film and a primer sub-layer, the method includes, before step (b), a step consisting of depositing by coating said primer sub-layer on the upper face of the plastic film.

24. Method according to claim 22, wherein it includes a step consisting of subjecting the plastic film to a corona effect treatment.

25. Method according to claim 19, wherein it includes, after step (b), a step consisting of causing the cross-linking of the matte varnish layer.
